(19) United States
(12) Patent Application Publication
(10) Pub. No.: US 2025/0233385 A1
(43) Pub. Date: Jul. 17, 2025

(54) PACKAGE STRUCTURE OF OPTICAL EMISSION MODULE AND PREPARATION METHOD

(71) Applicant: TRIPLE WIN TECHNOLOGY (SHENZHEN) CO. LTD., Shenzhen (CN)

(72) Inventors: Hsin-Yen Hsu, New Taipei (TW); Tzu-Li Feng, New Taipei (TW)

(21) Appl. No.: 19/014,515

(22) Filed: Jan. 9, 2025

(30) Foreign Application Priority Data
Jan. 16, 2024 (CN) 202410062402.8

(51) Int. Cl. H01S 5/02234

(52) U.S. Cl. CPC H01S 5/02234

(57) ABSTRACT

A package structure of an optical emission module and a preparation method thereof are provided. The package structure includes a substrate module and an optical emission module. The substrate module includes a substrate, and multiple channels are defined in the substrate module. The optical emission module is located on the substrate. Two ends of each channel extend to the substrate and the optical emission module, respectively. An inner wall of each channel is provided with a conductive layer to form a hollow conductive channel. The hollow conductive channel is electrically connected to the substrate and the optical emission module.

### FIELD

The subject matter herein generally relates to semiconductor packages, and more particularly, to a package structure of an optical emission module and a preparation method of the package structure.

### BACKGROUND

During 3D imaging of in a Time-of-flight (TOF) camera module, a vertical cavity surface emitting laser (VCSEL) provides phase-modulated laser beams. After the laser beams arrive and reflect by a target object, the camera module calculates a difference between a time at which the laser beams are emitted and a time at which the laser beams are received, thereby obtaining a distance between the target object and the camera and 3D information of the target object. The 3D imaging has great potential in physical recognition, posture recognition, and scene recognition.

In an existing VCSEL package structure, a circuit substrate may electrically connect to a chip through a wire bonding packaging technology or flip chip packaging technology. In the wire bonding packaging, the VCSEL is located on and electrically connected to a driving chip. The driving chip controls VCSEL to emit the laser beams. The driving chip is located on the circuit substrate and electrically connected to the circuit substrate through metal wires. However, since a certain space may be required for operating a wire bonding tool during the wire bonding packaging, a connection path between the driving chip and the circuit substrate may be long, which is not conducive to the miniaturization of the package structure. The flip chip packaging technology requires the circuit substrate to have a high flatness and symmetrically distributed solder joints, such that the flip chip packaging technology has a low universality. Improvements in the art are desired.

### BRIEF DESCRIPTION OF THE DRAWINGS

FIG. 1 is a diagrammatic view of a package structure of an optical emission module according to an embodiment of the present disclosure.

FIG. 2 is a diagrammatic view of the package structure of FIG. 1, when an optical lens and a base are removed.

FIG. 3 is similar to FIG. 2, but showing the package structure in another embodiment.

FIG. 4 is similar to FIG. 2, but showing the package structure in yet another embodiment.

FIG. 5 is similar to FIG. 2, but showing the package structure in yet another embodiment.

FIG. 6 is a top view of a board including a number of substrates according to an embodiment of the present disclosure.

FIG. 7 is a diagrammatic view showing a second plastic encapsulation block formed on an optical emission module according to an embodiment of the present disclosure.

FIG. 8 is a diagrammatic view showing the board of FIG. 6 stacked on the structure of FIG. 7 to obtain an intermediate body.

FIG. 9 is a diagrammatic view showing the intermediate body of FIG. 8 pressed together.

FIG. 10 is a diagrammatic view showing channels defined in a plastic encapsulation body of FIG. 9.

FIG. 11 is a diagrammatic view showing a conductive layer formed in the channel of FIG. 10.

FIG. 12 is a diagrammatic view of a package structure according to another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

In the wire bonding packaging technology, metal wires are used to connect the circuit substrate to the chip, thereby achieving the electrical connection between the chip and the circuit substrate. However, the wire bonding packaging technology requires an operation space for the wire bonding tool, resulting in a large lateral distance from the chip to the circuit substrate, which is not conducive to the miniaturization of the package structure. Also, the metal wires are thin and brittle, such that other components cannot be installed inside the space occupied by the metal wires.

In the flip chip packaging technology, metal balls or metal pillars are used to connect the circuit substrate to the chip, thereby achieving the electrical connection between the chip and the circuit substrate. In the flip chip packaging process, due to the size limitation of the metal balls, a high flatness of the circuit substrate is required. Furthermore, when the chip is soldered to the circuit substrate, to allow all solder points of the chip to be simultaneously soldered to the circuit substrate, the solder points need to be symmetrically distributed. As such, when pressure or ultrasonic energy is applied onto the chip, the energy may be uniformly transferred to the chip. Thus, the flip chip packaging technology has a low universality.

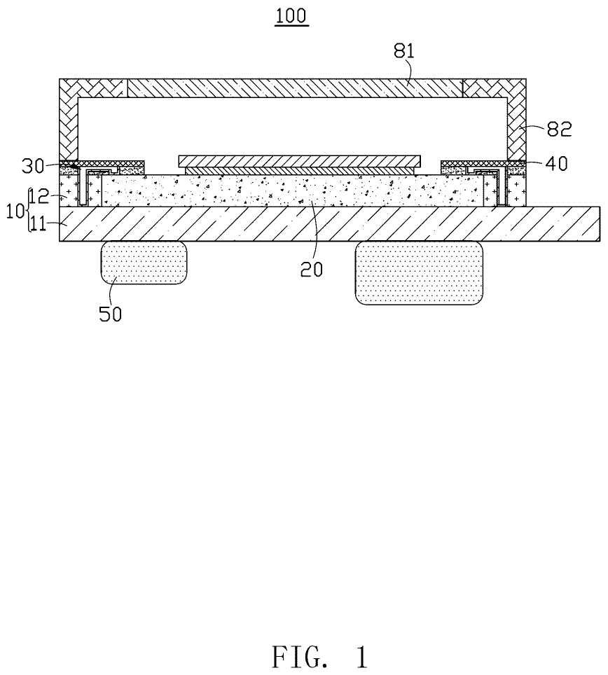

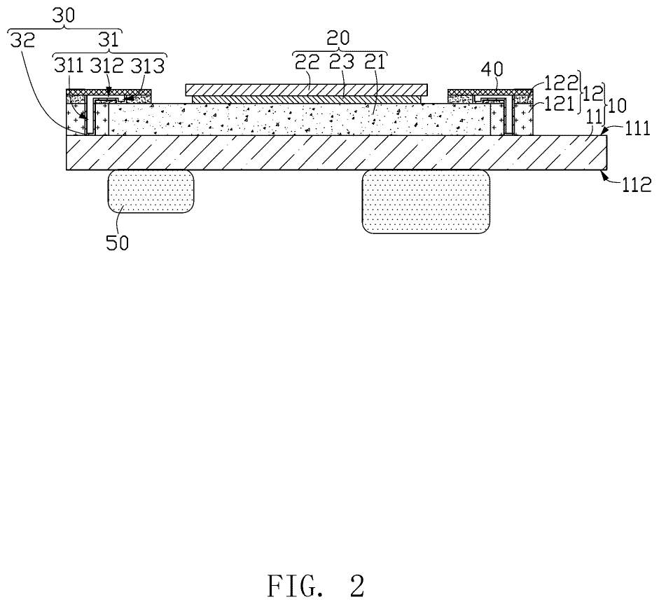

Referring to FIGS. 1 and 2, a package structure 100 is provided according to an embodiment of the present disclosure. The package structure 100 may be used to emit light. The package structure 100 includes a substrate module 10 and an optical emission module 20. The substrate module 10 includes a substrate 11. The optical emission module 20 is located on the substrate 11. The substrate module 10 defines a plurality of channels 31. Two ends of each of the channels 31 extend toward the substrate 11 and the optical emission module 20, respectively. A conductive layer 32 is formed on an inner wall of each of the channels 31 to form a hollow conductive channel 30. Two ends of the hollow conductive channel 30 are electrically connected to the substrate 11 and the optical emission module 20, respectively.

In the present disclosure, the hollow conductive channels 30 replace the metal wires in the related arts. The two ends of the hollow channel 31 are electrically connected to the substrate 11 and the optical emission module 20, respectively. That is, the two ends of the conductive layer 32 are electrically connected to electrical connection portions (such as solder pads) of the substrate 11 and the optical emission module 20. Thus, the existing metal wires are not needed in the present disclosure. Moreover, the shape of the channels 31 may be varied in the present disclosure according to needs, thereby adjusting the shape of the hollow conductive channels 30. Thus, the lateral path between the substrate 11 and the optical emission module 20 may be shortened without the limitation by the wire bonding tools. Moreover, since the shape of the channels 31 may also be changed according to the installation position of other components, the thickness of the package structure 100 may also be reduced to a certain extent. Since the metal wires are not needed in the present disclosure, the installation positions of other components will not be limited around the metal wires due to the brittleness of the metal wires, thereby facilitating the miniaturization of the package structure 100.

Meanwhile, compared to the flip chip packaging technology, the present disclosure forms the conductive layer 32 on the inner wall of the channel 31 to obtain the hollow conductive channel 30. Therefore, the package of the substrate 11 and the optical emission module 20 will not be limited by the size of the solder balls or by using symmetrically distributed solder joints. Thus, a high and strict flatness of the substrate 11 will not be need in the present disclosure.

Referring to FIG. 2, in some embodiments, the optical emission module 20 includes a driving chip 21 and a light source 22 electrically connected to the driving chip 21. The hollow conductive channel 30 is electrically connected to the substrate 11 and the driving chip 21. The light source 22 is located on the driving chip 21. The driving chip 21 outputs signals to drive the light source 22 to emit light. The light source 22 may be a vertical cavity surface emitting laser (VCSEL) or a vertical external cavity surface emitting semiconductor laser (VECSEL). The driving chip 21 may be a laser ranging chip. In some embodiments, there is also an electrical connection portion 23 between the driving chip 21 and the light source 22. The light source 22 is electrically connected to the driving chip 21 through the electrical connection portion 23. The electrical connection portion 23 may be made of a conductive adhesive or a solder paste. The substrate module 10 further includes a plastic encapsulation body 12, which is located on the substrate 11. The plastic encapsulation body 12 is at least adhered to the sidewall of the driving chip 21. The plastic encapsulation body 12 improves the stability of the package structure 100.

Referring to FIGS. 1 and 2, in some embodiments, the package structure 100 further includes an optical lens 81 and a base 82. The base 82 is located on the optical substrate module 10. The optical lens 81 is located on the base 82, and also on the light path of the optical emission module 20. In some embodiments, the base 82 is located on the plastic encapsulation body 12 or the substrate 11. When the base 82 is located on the plastic encapsulation body 12, the lateral size of the package structure 100 is further reduced. The embodiment takes the base 82 being located on the plastic encapsulation body 12 for example. The base 82 and the substrate module 10 cooperatively define a cavity, and the optical emission module 20 is located in the cavity. The optical lens 81 is disposed at a side of the base 82 away from the substrate 11. The optical lens 81 may be a transparent glass, a diffuser lens, a converging lens, and any combination thereof. The diffuser lens is used to adjust the travelling angle of the light emitted by the light source 22, and the converging lens is used to converge the light emitted by the light source 22. The light emitted by the light source 22 passes through the optical lens 81 and is directed towards the target object. The light is then reflected by the target object toward a receiving end (not shown), which converts the optical signal into electrical signal. The electrical signal is used to determine a distance between the target object and the receiving end, thereby obtaining the three-dimensional information of the target object.

In some embodiments, the substrate 11 includes a first surface 111 and a second surface 112 opposite to each other. The plastic encapsulation body 12 and the driving chip 21 are located on a same surface of the substrate 11. The channel 31 is located in the substrate 11 or the plastic encapsulation body 12. At least a portion of the channel 31 extends along a thickness direction of the package structure 100, which facilitates the drilling of the channel 31 and the forming of the conductive layer 32 in the channel 31. In some embodiments, a conductive ink is applied onto the inner wall of the channel 31 such as by spraying, and the conductive ink is solidified to form the conductive layer 32.

The package structure 100 will further be described as follows, when the driving chip 21 is located on the first surface 111 and the second surface 112, respectively.

### First Embodiment

Referring to FIG. 2, in the embodiment, the driving chip 21 is located on the first surface 111. The light source 22 is located on the driving chip 21. The plastic encapsulation body 12 is at least adhered to the sidewall of the driving chip 21. Channel 31 is located on plastic encapsulation body 12. The conductive layer 32 is formed on the inner wall of the channel 31 to form the hollow conductive channel 30. The hollow conductive channel 30 is electrically connected to the substrate 11 and the driving chip 21. For example, the conductive layer 32 in the hollow conductive channel 30 is electrically connected to the pads (not shown) of the substrate 11 and the driving chip 21, respectively.

In some embodiments, the channel 31 includes a first channel portion 311, a second channel portion 312, and a third channel portion 313. The second channel portion 312 is connected between the first channel portion 311 and the third channel portion 313. One end of the first channel portion 311 is connected to the substrate 11, and one end of the third channel portion 313 is connected to the driving chip 21. The plastic encapsulation body 12 may function as a carrier of the conductive layer 32. The shape and position of the channel 31 in the plastic encapsulation body 12 may be varied according to actual needs.

Referring to FIG. 2, in some embodiments, each of the first channel portion 311 and the third channel portion 313 extends in the plastic encapsulation body 12 along the thickness direction of the package structure 100. Each of the first channel portion 311 and the third channel portion 313 may be in a shape of a through hole. The second channel portion 312 extends in the plastic encapsulation body 12 or on the surface of the plastic encapsulation body 12 along a horizontal direction perpendicular to the above thickness. An end of the first channel portion 311 is sealed by the substrate 11, and the solder pad (not shown) of the substrate 11 is exposed from the first channel portion 311, thereby allowing the conductive layer 32 in the first channel portion 311 to be electrically connected to the solder pad. Similarly, an end of the third channel portion 313 is sealed by the driving chip 21, and the solder pad (not shown) of the driving chip 21 is exposed from the third channel portion 313, thereby allowing the conductive layer 32 in the third channel portion 313 to be electrically connected to the solder pad. In the embodiment, the solder pad of the driving chip 21 is located on the surface of the driving chip 21 away from the substrate 11. The light source 22 is located on the middle area of the driving chip 21.

Referring to FIG. 2, in some embodiments, the plastic encapsulation body 12 includes a first plastic encapsulation block 121 and a second plastic encapsulation block 122 located on the first plastic encapsulation block 121. The first plastic encapsulation block 121 is adhered to the sidewall of the driving chip 21, and the second plastic encapsulation block 122 covers the first plastic encapsulation block 121 and at least a portion of the driving chip 21. The first channel portion 311 extends through the first plastic encapsulation block 121 and the second plastic encapsulation block 122. The third channel portion 313 extends through the second plastic encapsulation block 122. The second channel portion 312 is exposed from the second plastic encapsulation block 122. The first plastic encapsulation block 121 and the second plastic encapsulation block 122 are fixed together by gluing. In some embodiments, the second channel portion 312 is located on the top surface of the second plastic encapsulation block 122 or recessed from the top surface of the second plastic encapsulation block 122. When the second channel portion 312 is located on the surface of the second plastic encapsulation block 122, a portion of the conductive layer 32 is laid flat on the second plastic encapsulation block 122. When the second channel portion 312 is a groove structure recessed from the top surface of the second plastic encapsulation block 122, and the opening of the groove faces away from the first plastic encapsulation block 121 (see FIG. 2). When the second channel portion 312 is a groove structure, it facilitates the subsequent spraying of the conductive ink onto the inner wall of the second channel portion 312, and the conductive ink is then solidified to form the conductive layer 32. The groove structure also facilitates the spraying of the conductive ink onto the inner wall of the entire channel 31 along the horizontal direction.

The second plastic encapsulation block 122 functions as a carrier of the second channel portion 312 and the third channel portion 313. Since the plastic encapsulation body 12 includes a first plastic encapsulation block 121 and a second plastic encapsulation block 122, during the package process, the second plastic encapsulation block 122 may first cover the driving chip 21, and then the first plastic encapsulation block 121 is adhered to the sidewall of the driving chip 21, which facilitates assembly of the plastic encapsulation body 12 and also improves the yield of the package structure 100. In other embodiments, the plastic encapsulation body 12 may also be integrally formed by injection molding on the driving chip 21.

In some embodiments, to avoid short circuits caused by electrical connection of the conductive layer 32 exposed from the second plastic encapsulation block 122 to other functional components, a protective film 40 is further provided on the second plastic encapsulation block 122. The protective film 40 covers the second channel portion 312. In some embodiments, the protective film 40 is laid over the entire surface of the second plastic encapsulation block 122. The protective film 40 may include an ultraviolet adhesive.

The package structure 100 according to the above embodiment has a flat surface, which facilitates the installation of the base 82 on the surface of the package structure 100. A difference between the total length of the package structure 100 and the length of the driving chip 21 may be less than 500 μm, and a difference between the total width of the package structure 100 and the width of the driving chip 21 is less than 500 μm. At the same time, the surface area of the package structure 100 is smaller than that of the package structure prepared by the wire bonding packaging technology and flip chip packaging technology. The thickness of the package structure 100 is also smaller than that of the package structure prepared by flip chip packaging technology.

In some embodiments, the conductive layer 32 includes a conductive ink. The conductive ink may be free of particles. The conductive ink may also include at least one element from silver, platinum, gold, copper, nickel, and aluminum.

In some embodiments, the package structure 100 further includes an electronic component 50. The electronic component 50 may be a passive component or an active component. The passive component includes a resistor or a capacitor. The active component includes a transistor, an integrated circuit, or a picture tube.

Referring to FIG. 2, in some embodiments, the electronic component 50 is located on the second surface 112 of the substrate 11.

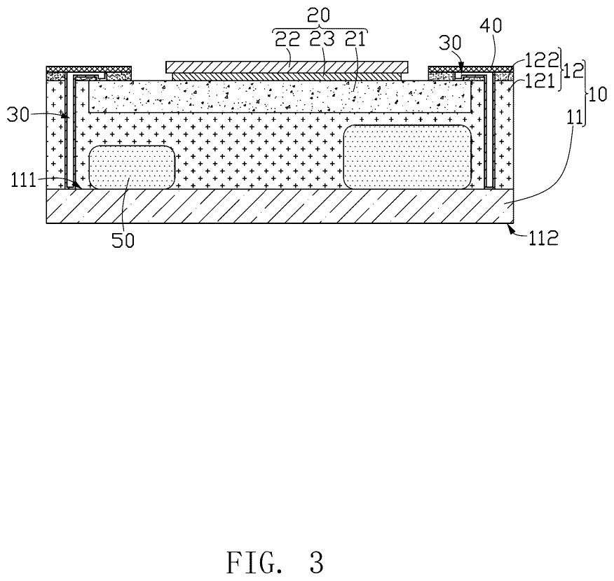

Referring to FIG. 3, in other embodiments, the electronic component 50 is located on the first surface 111 of the substrate 11 and embedded in the plastic encapsulation body 12. For example, the electronic component 50 is embedded in the first plastic encapsulation block 121. The electronic component 50 is sealed between driving chip 21 and the substrate 11. The first plastic encapsulation block 121 is located between the driving chip 21 and the substrate 11, and extends out of the driving chip 21 to wrap around the sidewall of the driving chip 21, thereby improving the stability of the driving chip 21 and the electronic component 50.

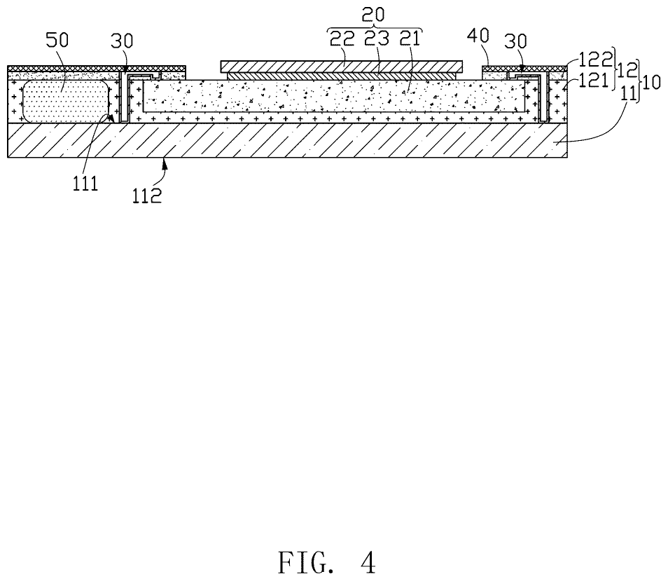

Referring to FIG. 4, in other embodiments, the electronic component 50 is located on one side of the driving chip 21 and embedded in the first plastic encapsulation block 121.

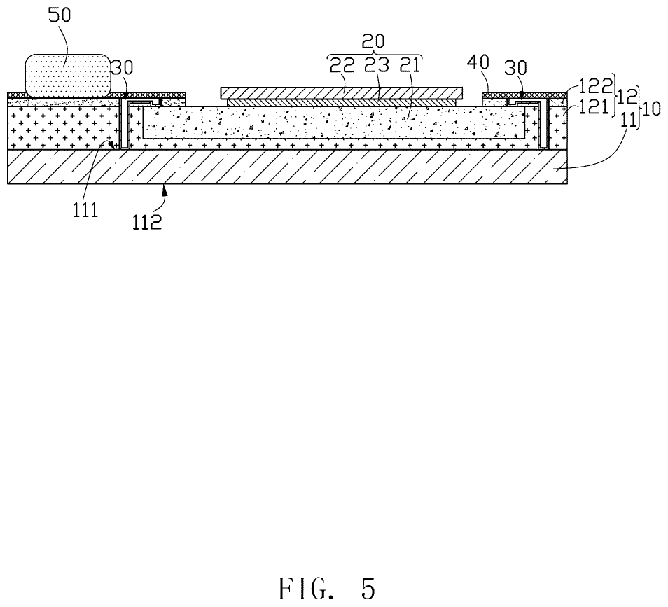

Referring to FIG. 5, in other embodiments, the electronic component 50 is located on one side of the driving chip 21 and on the plastic encapsulation body 12. The electronic component 50 is not sealed by the plastic encapsulation body 12.

In some embodiments, the thickness of the conductive layer 32 is greater than or equal to 500 nm. The conductive ink is sprayed onto the inner wall of the channel 31 and solidified to obtain the desired thickness. The thickness of the conductive layer 32 may also be varied according to actual needs, such that the impedance of the conductive layer 32 may be adjusted.

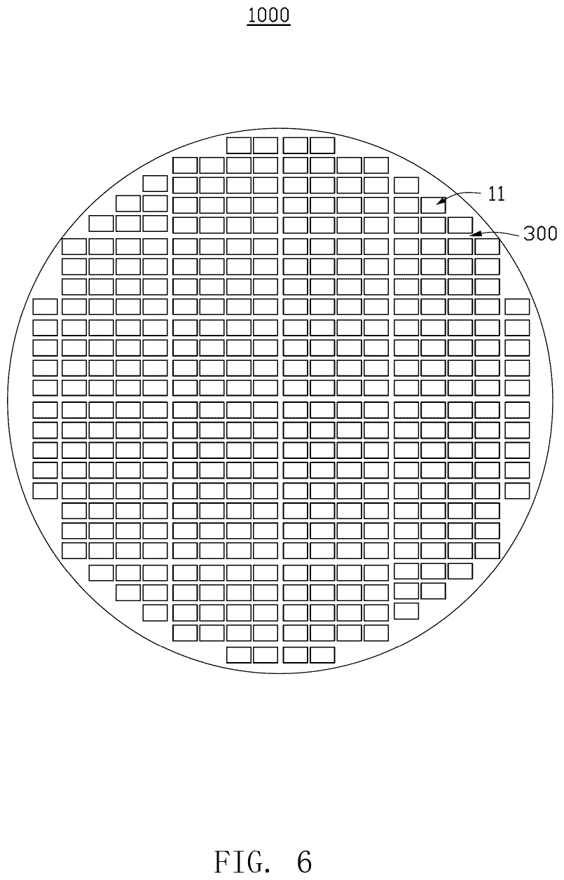

FIGS. 6 to 11 illustrate a preparation method of the package structure 100 in accordance with an embodiment. The method is provided by way of embodiments, as there are a variety of ways to carry out the method. The method can begin at step S1.

Step S1, referring to FIG. 6, a board 1000 is provided, which includes multiple substrates 11 arranged in arrays. Two adjacent substrates 11 form a cutting area 300 therebetween.

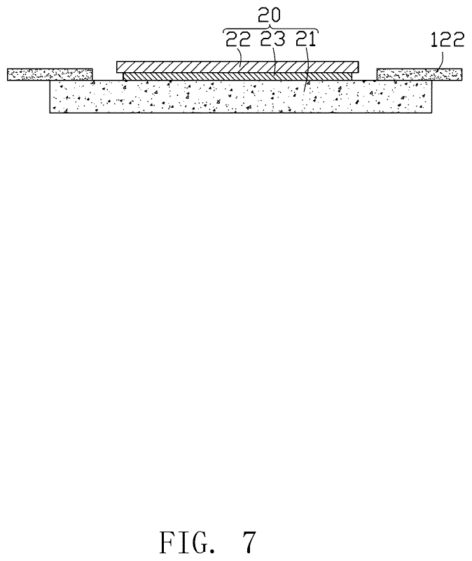

Step S2, referring to FIGS. 7 to 9, each substrate 11 is fabricated into a package unit 200. The fabrication of the package unit 200 may be carried out by the following steps.

(1) Referring to FIG. 7, an optical emission module 20 and a second plastic encapsulation block 122 are provided. The optical emission module 20 includes a driving chip 21 and a light source 22 electrically connected to the driving chip 21. The second plastic encapsulation block 122 is adhered onto a surface of the driving chip 21.

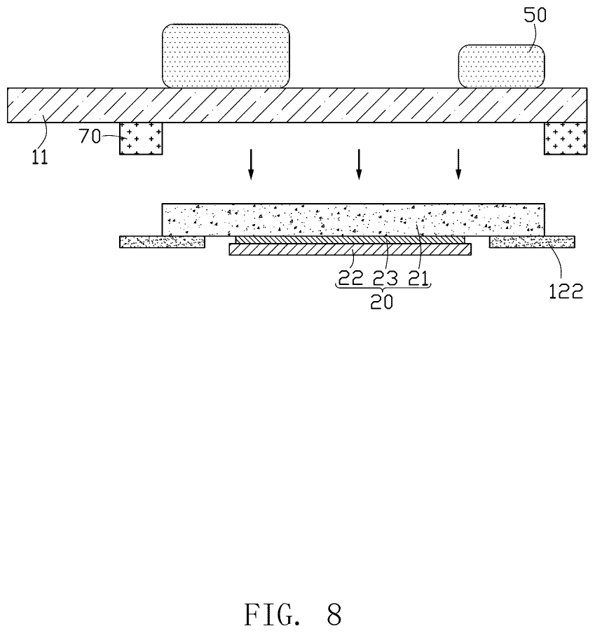

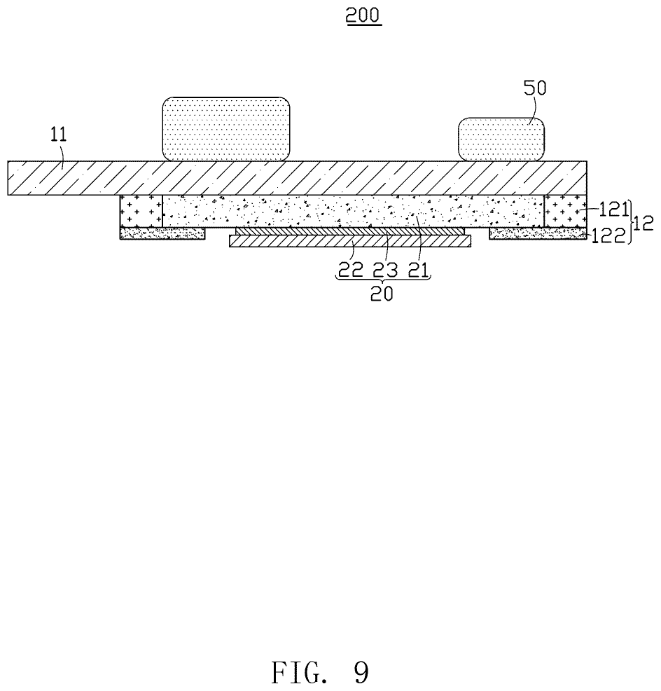

(2) Referring to FIGS. 8 and 9, the optical emission module 20 with the second plastic encapsulation block 122 is pressed and fixed onto one substrate 11. The substrate 11 further has a plastic encapsulation preform 70 thereon. The plastic encapsulation preform 70 may be formed on the substrate 11 by coating. After the pressing, the plastic encapsulation preform 70 is at least adhered to the sidewall of the driving chip 21. The driving chip 21 may be adhered to the substrate 11 through an insulating adhesive layer. At least a portion of the plastic encapsulation preform 70 is located between the second plastic encapsulation block 122 and the substrate 11.

In some embodiments, the electronic component 50 is adhered to the surface of substrate 11 away from the driving chip 21. The electronic component 50 may also be embedded in the plastic encapsulation preform 70 and located between the driving chip 21 and the substrate 11, and at this time, the plastic encapsulation preform 70 is located between the driving chip 21 and the substrate 11, and extends to the sidewall of the driving chip 21. The electronic component 50 may also be embedded in the plastic encapsulated preform 70 and located on one side of the driving chip 21. The electronic component 50 may also be located on one side of the driving chip 21 and on the plastic encapsulation body 12, and the electronic component 50 is not sealed by the plastic encapsulation body 12. The position of the electronic component 50 may be set according to actual needs.

In some embodiments, the plastic encapsulated preform 70 is made of at least one of epoxy resin and phenolic resin. The second plastic encapsulation block 122 is made of at least one of polyimide adhesive, ultraviolet adhesive, black adhesive, and silicone.

(3) The plastic encapsulation preform 70 is solidified to obtain the first plastic encapsulation block 121. The first plastic encapsulation block 121 and the second plastic encapsulation block 122 constitute the plastic encapsulation body 12.

The plastic encapsulation preform 70 may be solidified by heating and pressure, thereby obtaining the first plastic encapsulation block 121 with stable structure and high strength in which the driving chip 21 is embedded. The first plastic encapsulation block 121 is located between the second plastic encapsulation block 122 and the substrate 11. After the plastic encapsulation preform 70 is heated and solidified, the first plastic encapsulation block 121 is adhered to the second plastic encapsulation block 122.

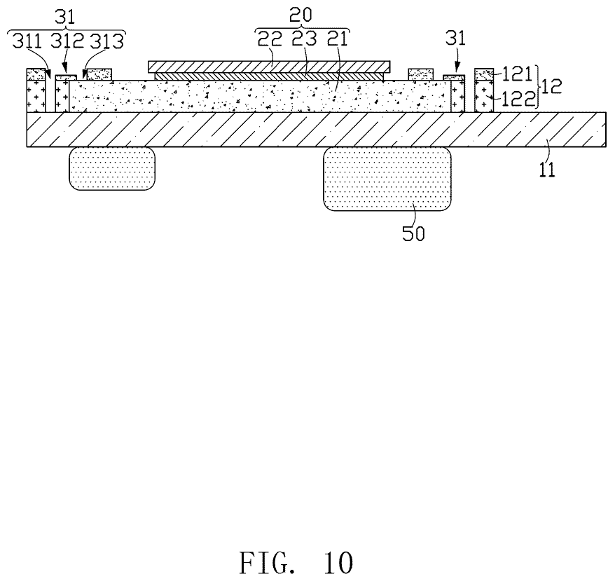

Step S3, referring to FIG. 10, a number of channels 31 are defined in the plastic encapsulation body 12 of the package unit 200, and the two ends of each of the channels 31 extend toward the substrate 11 and the driving chip 21, respectively.

The channel 31 includes a first channel portion 311, a second channel portion 312, and a third channel portion 313. The second channel portion 312 is connected between the first channel portion 311 and the third channel portion 313. Each of the first channel portion 311 and the third channel portion 313 extends along the thickness direction of the driving chip 21. One end of the first channel portion 311 is connected to the substrate 11, and one end of the third channel portion 313 is connected to the driving chip 21. The second channel portion 312 is exposed from the second plastic encapsulation block 122.

In some embodiments, the first channel portion 311 and the third channel portion 313 may be obtained by drilling, such as laser drilling, along the thickness direction of the package unit 200. In some embodiments, the second channel portion 312 is drilled on the surface of the second plastic encapsulation block 122 along a horizontal direction perpendicular to the thickness direction of the package unit 200, thereby obtaining a groove structure with an opening facing away from the substrate 11. In other embodiments, the second channel portion 312 may also be located on the top surface of the second plastic encapsulation block 122, and no drilling treatment is performed on the second plastic encapsulation block 122.

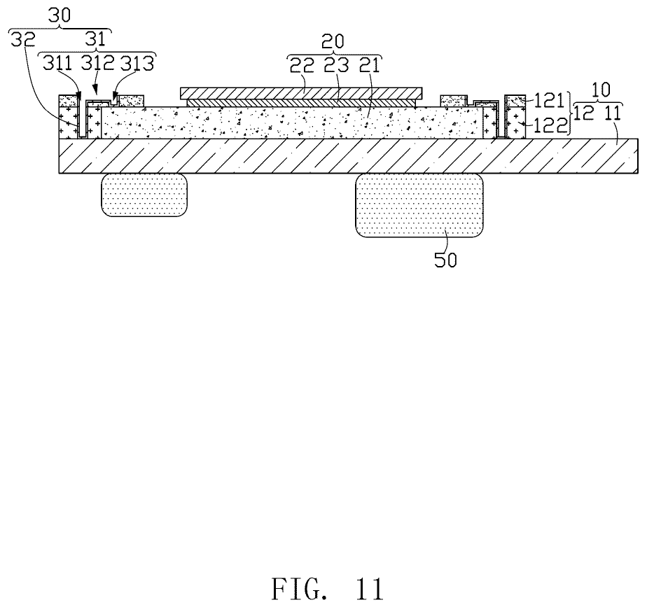

Step S4, referring to FIG. 11, a conductive material is sprayed onto the inner wall of the channel 31. The conductive material is solidified to form a conductive layer 32 on the inner wall of the channel 31, thereby obtaining a hollow conductive channel 30. The conductive layer 32 in the hollow conductive channel 30 is electrically connected to the driving chip 21 and the substrate 11.

The conductive material may be sprayed onto the inner wall of the first channel portion 311, the second channel portion 312, and the third channel portion 313 of the channel 31 in sequence by a nozzle. The conductive material may include a conductive ink. When the conductive ink is used, and the inner diameter of the channel 31 may be less than 50 μm. If other conductive materials (such as conductive silver paste) are used, the inner diameter of channel 31 should be greater than 250 μm to enable the conductive silver paste to successively form inside the channel 31. Thus, by using the conductive ink in the present disclosure, the channel 31 may be formed with a small diameter, which is conducive to the miniaturization of the package structure 100.

When the conductive material includes the conductive ink, the solidification of the conductive ink includes a first solidification stage and a second solidification stage after the first solidification stage.

The first solidification stage includes irradiating the conductive ink with ultraviolet light after the conductive ink is sprayed onto the inner wall of the channel 31, thereby pre-solidifying the conductive ink. At the first solidification stage, the ultraviolet irradiation is used to rapidly pre-solidify the conductive ink and prevent the flow of the conductive ink. The ultraviolet irradiation may be performed for a few seconds, such as for 1 second to 5 seconds.

The second solidification stage includes baking the pre-solidified conductive ink to obtain the conductive layer 32, thereby forming the hollow conductive channel 30. After the first solidification stage, the conductive ink is pre-formed on the inner wall of channel 31. The conductive ink is then baked at a temperature of 60° C. to 100° C. for a duration of 0.5 h to 3 h, thereby allowing the conductive ink to be completely solidified on the inner wall of the channel 31.

Step S5, referring to FIG. 2, a protective film 40 is coated on the second plastic encapsulation block 122 to obtain the encapsulation structure 100.

The protective film 40 blocks the second channel portion 312 and prevents short circuits caused by the conductive layer 32 in the second channel portion 312 being in contact with other components in the package structure 100.

After the protective film 40 is formed on the package unit 200, the board 1000 is cut along the cutting area 300 to obtain a number of package structures 100.

In the present disclosure, the hollow conductive channel 30 is formed by defining the channel 31 in the substrate module 10 and forming the conductive layer 32 inside the channel 31. The hollow conductive channel 30 can achieve the electrical connection between the substrate 11 and the driving chip 21, eliminating the need for metal wires. Thus, the lateral path between the substrate 11 and the optical emission module 20 may be shortened without the limitation by the wire bonding tools. Moreover, since the shape of the channels 31 may also be changed according to the installation position of other components, the thickness of the package structure 100 may also be reduced to a certain extent. Since the metal wires are not needed in the present disclosure, the installation positions of other components will not be limited around the metal wires due to the brittleness of the metal wires, thereby facilitating the miniaturization of the package structure 100.

### Second Embodiment

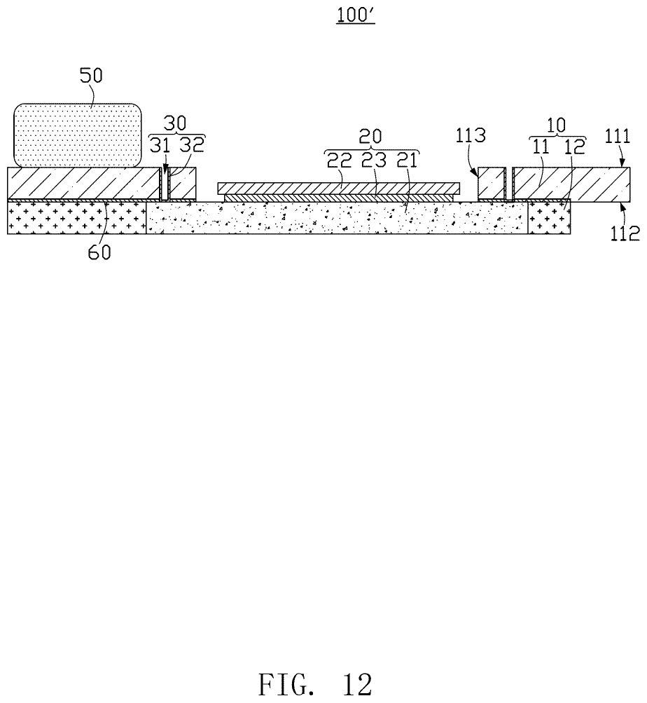

A package structure 100′ is also provided according to another embodiment of the present disclosure. The difference between the package structure 100′ and the package structure 100 includes that the substrate 11 defines a slot 113 as shown in FIG. 12, and the driving chip 21 is installed on the second surface 112 in a flipped manner. The light source 22 is received in the slot 113. The channel 31 is located in substrate 11 and extends through the substrate 11, and one end of the channel 31 extends toward the driving chip 21. The conductive layer 32 is formed on the inner wall of channel 31 to obtain the hollow conductive channel 30. The hollow conductive channel 30 is electrically connected to the substrate 11 and the driving chip 21.

In the embodiment, the channel 31 extends along the thickness direction of the driving chip 21, and the solder pad of the driving chip 21 is exposed from the channel 31. The two ends of the conductive layer 32 in the hollow conductive channel 30 are electrically connected to the solder pad of the driving chip 21 and the substrate 11, respectively.

In the embodiment, the plastic encapsulation body 12 is made of a same material of the first plastic encapsulation block 121 in the first embodiment. No second plastic encapsulation block 122 is included. The plastic encapsulation body 12 is located on the sidewall of the driving chip 21. There is also an adhesive layer 60 between the driving chip 21 and the second surface 112. The plastic encapsulation body 12 is also adhered to the second surface 112 through the encapsulation body layer 60.

The difference between the preparation methods of the package structure 100′ and the package structure 100 includes that when preparing the package unit 200, step (1) for forming the second plastic encapsulation block 122 in the first embodiment is omitted, and the driving chip 21 is located on the second surface 112 of the substrate 11.

Furthermore, at step S2, the hollow conductive channel 30 is located in the substrate 11. For example, the channel 31 is first defined in the substrate 11, the conductive material (such as conductive ink) is sprayed onto the inner wall of the channel 31, and the conductive material is solidified to form the conductive layer 32, thereby forming the hollow conductive channel 30. The hollow conductive channel 30 is electrically connected to driving chip 21 and the substrate 11.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A package structure comprising:
a substrate module comprising a substrate, the substrate module defining a plurality of hollow conductive channels; and
an optical emission module located on the substrate;
wherein each of the plurality of hollow conductive channels comprises a channel and a conductive layer formed on an inner wall of the channel, two ends of the channel extend to the substrate and the optical emission module, respectively, and each of the plurality of hollow conductive channels is electrically connected to the substrate and the optical emission module.

2. The package structure according to claim 1, wherein the optical emission module comprises a driving chip and a light source electrically connected to the driving chip, the substrate comprises a first surface and a second surface opposite to each other, the substrate module further comprises a plastic encapsulation body, the plastic encapsulation body and the driving chip are located on one of the first surface and the second surface, and the plastic encapsulation body is at least adhered to a sidewall of the driving chip.

3. The package structure according to claim 2, wherein the light source is located on the driving chip, the driving chip is located on the first surface, the channel is defined in the plastic encapsulation body, the channel comprises a first channel portion, a second channel portion, and a third channel portion, the second channel portion is connected between the first channel portion and the third channel portion, one end of the first channel portion is connected to the substrate, and one end of the third channel portion is connected to the driving chip.

4. The package structure according to claim 3, wherein the plastic encapsulation body comprises a first plastic encapsulation block and a second plastic encapsulation block located on the first plastic encapsulation block, the first plastic encapsulation block is adhered to the sidewall of the driving chip, the second plastic encapsulation block at least covers a portion of a surface of the driving chip facing away from the substrate, the first channel portion extends through the first plastic encapsulation block and the second plastic encapsulation block, the third channel portion extends through the second plastic encapsulation block, and the second channel portion is exposed from the second plastic encapsulation block.

5. The package structure according to claim 4, further comprising a protective film, wherein the protective film is formed on the second plastic encapsulation block and covers the second channel portion.

6. The package structure according to claim 2, wherein the substrate defines a slot, the driving chip is located on the second surface, the light source is received in the slot, the channel extends through the substrate, and one end of the channel extends to the driving chip.

7. The package structure according to claim 1, wherein the conductive layer comprises a conductive material, and the conductive material comprises a conductive ink or a conductive silver paste.

8. The package structure according to claim 1, further comprising an optical lens, wherein the optical lens is located on the substrate module, and further positioned on a light path of the optical emission module.

9. The package structure according to claim 2, further comprising an electronic component, wherein the electronic component is embedded in the plastic encapsulation body, or located on the plastic encapsulation body, or located on the substrate.

10. The package structure according to claim 1, wherein a thickness of the conductive layer is greater than or equal to 500 nm.

11. A preparation method of a package structure, comprising:
forming an optical emission module on a substrate of a substrate module;
defining a plurality of channels in the substrate module, wherein two ends of each of the plurality of channels extend to the substrate and the optical emission module, respectively; and
forming a conductive layer on an inner wall of each of the plurality of channels to form a hollow conductive channel, wherein the hollow conductive channel is electrically connected to the substrate and the optical emission module, thereby obtaining the package structure.

12. The preparation method according to claim 11, wherein the optical emission module comprises a driving chip and a light source electrically connected to the driving chip, the hollow conductive channel is electrically connected to the substrate and the driving chip; the substrate module further comprises a plastic encapsulation body, the substrate comprises a first surface and a second surface opposite to each other, the plastic encapsulation body and the driving chip are located on one of the first surface and the second surface, the plastic encapsulation body is at least adhered to a sidewall of the driving chip, and the plurality of channels is located on the substrate or the plastic encapsulation body.

13. The preparation method according to claim 12, wherein the plurality of channels is located in the plastic encapsulation body, and forming the driving chip on the substrate comprises:
forming a second plastic encapsulation block on the first surface of the driving chip;
installing the driving chip with the second plastic encapsulation block on the substrate, wherein the substrate further comprises a plastic encapsulation preform thereon, and the plastic encapsulation preform is at least adhered to the sidewall of the driving chip; and
solidifying the plastic encapsulation preform to obtain a first plastic encapsulation block, wherein the first plastic encapsulation block and the second plastic encapsulation block constitute the plastic encapsulation body.

14. The preparation method according to claim 12, wherein the plurality of channels is located in the substrate, and forming the driving chip on the substrate comprises:
installing the driving chip on the second surface, wherein the substrate defines a slot, the light source is received in the slot, a plastic encapsulation preform is provided on the second surface, the plastic encapsulation preform is at least adhered to the sidewall of the driving chip; and
solidifying the plastic encapsulation preform to obtain the plastic encapsulation body.

15. The preparation method according to claim 11, wherein forming the conductive layer on the inner wall of each of the plurality of channels comprises:
forming a conductive material on the inner wall of each of the plurality of channels; and
solidify the conductive material to form the conductive layer.

16. The preparation method according to claim 15, wherein the conductive material comprises a conductive ink or a conductive silver paste.

17. The preparation method according to claim 16, wherein solidify the conductive material comprises a first solidification stage and a second solidification stage after the first solidification stage;
the first solidification stage comprises spraying the conductive ink onto the inner wall of each of the plurality of channels, and irradiating the conductive ink with ultraviolet light to pre-solidify the conductive ink; and
the second solidification stage comprises baking the pre-solidified conductive ink to obtain the conductive layer.

18. The preparation method according to claim 12, further comprising:
providing a board comprising a plurality of substrates arranged in arrays, wherein adjacent two of the plurality of substrates form a cutting area therebetween;
fabricating each of the plurality of substrates into a package unit, wherein the package unit comprises one of the plurality of substrates, the driving chip, and the plastic encapsulation body located on the one of the plurality of substrates; and
forming the conductive layer in the package unit to form the hollow conductive channel, and cutting the board along the cutting area to obtain a plurality of package structures.
